(19) United States
(12) Patent Application Publication
(10) Pub. No.: US 2008/0303443 A1
(43) Pub. Date: Dec. 11, 2008

(54) POSITION LOCK TRIGGER

(75) Inventors: Que Thuy Tran, Beaverton, OR (US); David L. Kelly, Portland, OR (US); David G. Hite, Hillsboro, OR (US); Patrick A. Smith, Beaverton, OR (US); Thomas F. Lenihan, West Linn, OR (US)

Correspondence Address: WILLIAM K. BUCHER;TEKTRONIX, INC., 14150 S.W. KARL BRAUN DRIVE, P.O. BOX 500, MS 50-LAW, BEAVERTON, OR, 97077, US

(73) Assignee: TEKTRONIX, INC., Beaverton, OR (US)

(21) Appl. No.: 12/135,085

(22) Filed: Jun. 6, 2008

Related U.S. Application Data
(60) Provisional application No. 60/942,795, filed on Jun. 8, 2007.

(51) Int. Cl. G01R 13/32

(52) U.S. Cl. 315/1

(57) ABSTRACT

Position Lock Trigger apparatus employs oscilloscope circuitry and accompanying control software to provide to a user the capability to trigger an oscilloscope on a selected bit position in a received serial bit stream having a fixed pattern length, using either a synthesized, recovered, or external clock source. The selected trigger position can be moved forward and backward along the serial bit stream by one or more serial bit positions at a time in order to examine the entirety of the fixed pattern length serial bit stream, with or without regard to the actual bit sequences occurring in the serial stream.

### CLAIM FOR PRIORITY

The subject application claims priority from U.S. Provisional patent application Ser. No. 60/942,795, POSITION LOCK TRIGGER (Que T. Tran, et al.), filed 8 Jun. 2007, and herein incorporated by reference in its entirety.

### FIELD OF THE INVENTION

The subject invention generally concerns the field of test and measurement instruments, such as, digital storage oscilloscopes, and specifically concerns triggering of such an oscilloscope from a serial bit stream signal.

### BACKGROUND OF THE INVENTION

The trigger function of an oscilloscope synchronizes the horizontal sweep at the correct point in the acquired signal to ensure stable display of the signal. Modern oscilloscopes provide many trigger functions to assist the operator in attaining such a stable display. For example, the DPO7000-series digital storage oscilloscopes, manufactured by Tektronix, Inc., Beaverton, Oreg., provide the following triggering modes: Edge, glitch, width, runt, timeout, and transition, each of which responds to a corresponding characteristic of the received signal. Of these, the most widely used trigger mode is edge trigger. However, as good as edge trigger mode is, there are some signals that by their very nature may be unsuitable for use with edge trigger mode. A serial bit stream comprises a large number of vertical edges in any given time. An oscilloscope in edge trigger mode will trigger on the first suitable edge that it receives. This edge may, or may not, be in the particular portion of the waveform that the operator would like to see.

A prior solution to this problem is that of Serial Triggering. That is, examining the incoming serial waveform to find a particular pattern (i.e., word) and triggering upon its detection. Unfortunately, Serial Pattern Trigger circuits used in modern digital storage oscilloscopes (DSOs) require sophisticated, expensive, and high-power circuits with similarly complex control software to trigger on a serial bit streams by means of matching a bit pattern known to occur in a serial data stream. The design sophistication, cost, power requirements, and software complexity increase quickly with increasing bit rate of the signal. What is needed is a serial trigger circuit that overcomes these difficulties.

### SUMMARY OF INVENTION

Position Lock Trigger apparatus employs oscilloscope circuitry and accompanying control software to provide to a user the capability to trigger an oscilloscope on a selected bit position in a serial bit stream having a fixed pattern length, using either a synthesized, recovered, or external clock source. The selected trigger position can be moved forward and backward along the serial bit stream by one or more serial bit positions at a time in order to examine the entirety of the fixed pattern length serial bit stream, with or without regard to the actual bit sequences occurring in the serial stream.

### BRIEF DESCRIPTION OF THE DRAWING

FIG. 1 show, in simplified block diagram form, the Position Locking and Bumping Circuit and its Logic Signal Traces, in accordance with the subject invention.

FIG. 2 shows, in simplified block diagram form, a first embodiment of a Position Locking and Bumping Circuit in accordance with the subject invention.

FIGS. 3a, 3b, and 3c show Logic Signal Traces useful in understanding the embodiment of FIG. 2.

FIG. 4 shows, in simplified block diagram form, a second embodiment of a Position Locking and Bumping Circuit in accordance with the subject invention.

FIGS. 5a, 5b, and 5c show Logic Signal Traces useful in understanding the embodiment of FIG. 2.

### DETAILED DESCRIPTION OF THE EMBODIMENTS

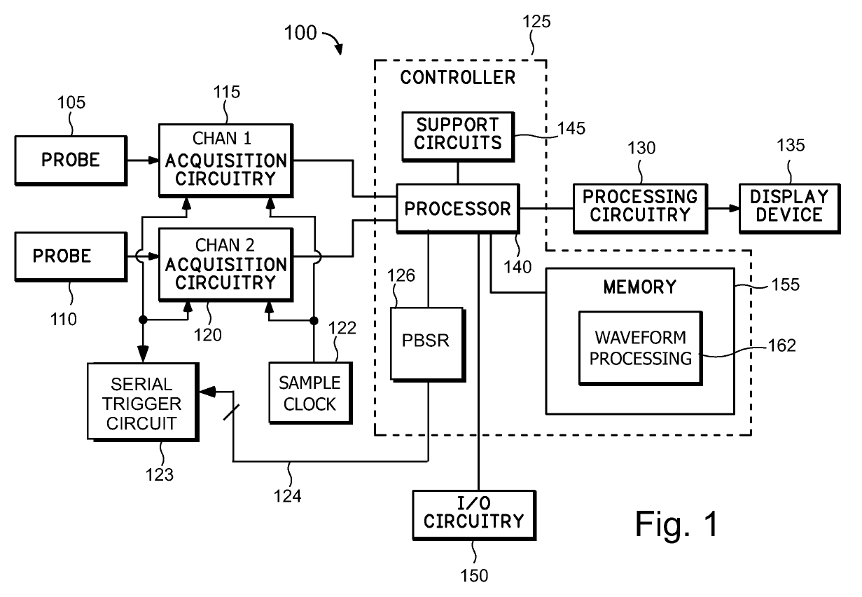

FIG. 1 depicts a high level block diagram of an oscilloscope 100 in accordance with the subject invention. In particular, oscilloscope 100 utilizes a first probe 105 and a second probe 110, and comprises Channel 1 Acquisition circuitry 115, Channel 2 Acquisition circuitry 120, a Controller 125, processing circuitry 130, and a display device 135. Probe 105 and probe 110 may be any conventional voltage or current probes suitable for respectively detecting analog voltage or current signals from a device under test (DUT) (not shown).

For example, probes 105 and 110 may be any suitable probes which may be used to acquire real time signal information. Such probes are manufactured by Tektronix, Inc., Beaverton, Oreg. The output signals of probes 105 and 110 are respectively sent to the Channel 1 Acquisition circuitry 115 and Channel 2 Acquisition circuitry 120.

The Channel 1 Acquisition circuitry 115 and Channel 2 Acquisition circuitry 120 each include, illustratively, analog-to-digital conversion circuitry, triggering circuitry, decimator circuitry, supporting Acquisition memory, and the like. Acquisition circuitry 115 and 120 operate to digitize, at a sample rate, “SR”, one or more of the signals under test to produce one or more respective sample streams suitable for use by Controller 125 or processing circuitry 130. Acquisition circuitry 115 and 120, in response to commands received from Controller 125, change trigger conditions, decimator functions, and other Acquisition related parameters. Acquisition circuitry 115, 120 communicates its respective resulting sample stream to Controller 125.

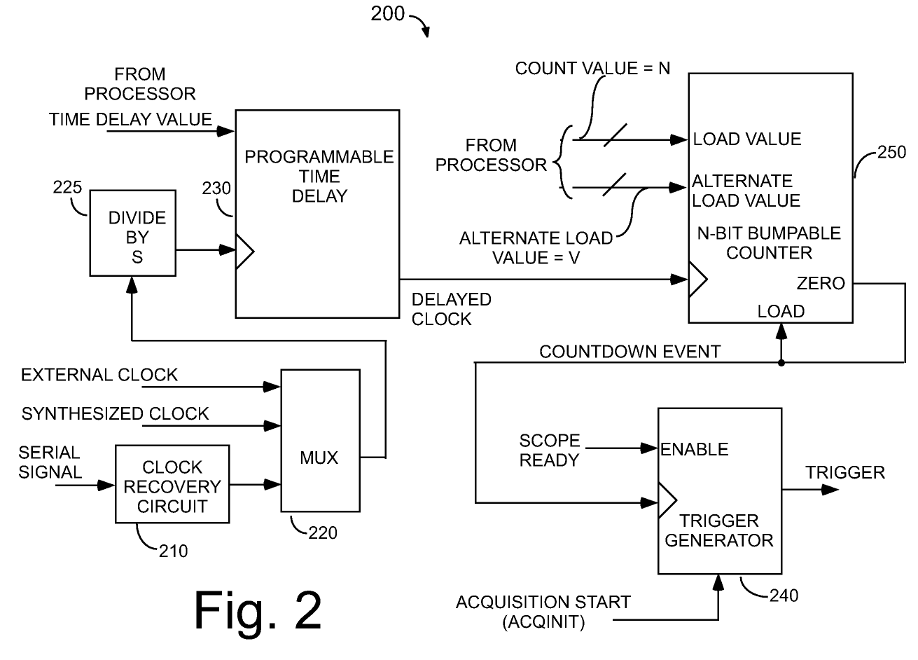

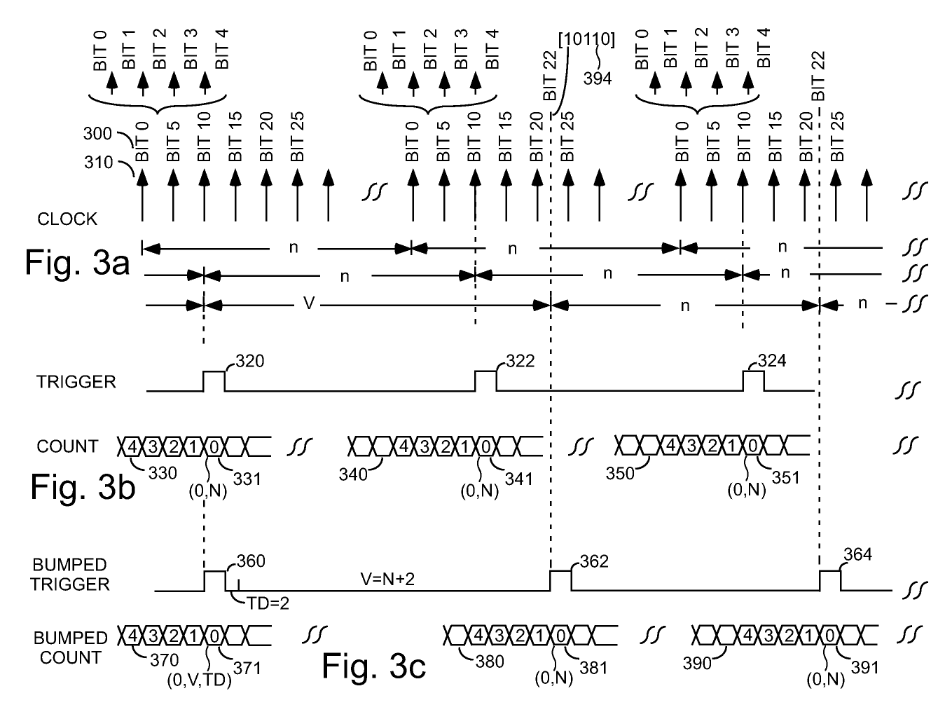

A Serial Trigger circuit 123 is shown separate from Channel 1 Acquisition circuitry 115 and Channel 2 Acquisition circuitry 120 for purposes of explanation, but one skilled in the art will realize that it could be internal to the acquisition circuitry. Serial trigger circuit 123 receives the real time sample stream signal acquired by, for example, channel 1 probe 105 and, for certain applications, receives an external clock signal acquired by, for example channel 2 probe 110. Serial trigger circuit 123 receives two N-bit LOAD VALUE signals via a bus 124 from processor 140 of controller 125. An optional Pattern Bit Sequence Recognizer 126 may be provided in the controller 125 for recognizing a pattern bit sequence in serial bit sequence data generated by the Acquisition circuitry 115 and 120. Serial Trigger circuit 123 and the optional Pattern Bit Sequence Recognizer 126 will be described in detail with respect to FIGS. 2 and 3a, 3b, and 3c.

Controller 125 operates to process the one or more acquired sample streams provided by the Acquisition circuitry 115 and 120 to generate respective sample stream data associated with one or more sample streams. That is, given desired time per division and volts per division display parameters, Controller 125 operates to modify or rasterize the raw data associated with an acquired sample stream to produce corresponding waveform data having the desired time per division and volts per division parameters. Controller 125 may also normalize waveform data having non-desired time per division, volts per division, and current per division parameters to produce waveform data having the desired parameters. Controller 125 provides the waveform data to processing circuitry 130 for subsequent presentation on display device 135.

Processing circuitry 130 comprises data processing circuitry suitable for converting acquired sample streams or waveform data into image or video signals, which are adapted to provide visual imagery (e.g., video frame memory, display formatting and driver circuitry, and the like). Processing circuitry 130 may include display device 135 (e.g., a built-in display device) or provide output signals (e.g., via a video driver circuit) suitable for use by an external display device 135.

Controller 125 of FIG. 1 preferably comprises a Processor 140, support circuits 145 and Memory 155. Processor 140 cooperates with conventional support circuitry 145, such as power supplies, clock circuits, cache memory, and the like, as well as circuits that assist in executing software routines stored in Memory 155. As such, it is contemplated that some of the process steps discussed herein as software processes may be implemented within hardware, for example, as circuitry that cooperates with Processor 140 to perform various steps. Controller 125 also interfaces with input/output (I/O) circuitry 150. For example, I/O circuitry 150 may comprise a keypad, pointing device, touch screen, or other means adapted to provide user input and output to Controller 125. Controller 125, in response to such user input, adapts the operations of Acquisition circuitry 115 and 150 to perform various data Acquisitions, triggering, processing, and display communications, among other functions. In addition, the user input may be used to trigger automatic calibration functions or adapt other operating parameters of display device 135, logical analysis, or other data acquisition devices.

Memory 155 may include volatile memory, such as SRAM, DRAM, among other volatile memories. Memory 155 may also include non-volatile Memory devices, such as a disk drive or a tape medium, among others, or programmable memory, such as an EPROM, among others.

Although Controller 125 of FIG. 1 is depicted as a general purpose computer that is programmed to perform various control functions in accordance with the present invention, the invention may be implemented in hardware such as, for example, an application specific integrated circuit (ASIC). As such, it is intended that Processor 125, as described herein, be broadly interpreted as being equivalently performed by hardware, software, or by a combination thereof.

It will be appreciated by those skilled in the art that standard signal processing components (not shown), such as signal buffering circuitry, signal conditioning circuitry, and the like are also employed as required to enable the various functions described herein. For example, Acquisition circuitry 115 and 120 sample the signals under test at a sufficiently high rate to enable appropriate processing by Controller 125 or Processing circuitry 130. In this regard, Acquisition circuitry 115 and 120 sample their respective input signals in accordance with a sample clock provided by an internal Sample Clock Generator 122.

FIG. 2 is a more detailed view of a first embodiment of Serial Trigger block 123 of FIG. 1. Referring to FIG. 2, controlling a locked trigger position is accomplished by use of a coarse trigger adjustment and a fine trigger adjustment. The coarse trigger adjustment positions a trigger by at least a value that equally divides the pattern length “n” into divided segments and the fine trigger adjustment positions the trigger within the divided segments of the pattern length “n”. The locked trigger position “shifts” left or right along the received serial bit sequences of the sample stream by increasing or decreasing the coarse and fine trigger adjustments bringing a different portion of the received serial bit sequences into view. In this way, a stable view of the received data at any position along the serial bit sequences is obtained.

The first embodiment of the subject invention will now be described with respect to FIGS. 2, 3a, 3b, and 3c. Position Lock Trigger circuitry 200 includes at least a first input for receiving an external clock, a clock signal derived by use of a Clock Recovery Circuit 210, or a synthesized clock signal based on a requested bit rate or additional inputs for receiving two or more of the clock signals. In the event that two or more clock choices are provided, a Multiplexer (MUX) 220 is provided to select one of the multiple clock signals. The selected clock is applied to a Divide by “S” circuit 225. The “divided down clock” from Divide by S circuit 225 is applied to an input of a Programmable Time Delay unit 230. In the preferred embodiment, “S” has a value of 2, 5 or 10 to divide a clock signal having a frequency greater than the operating characteristics of an N-bit Bumpable counter 250. It is noted that other divide-by values may be employed without departing from the scope of the present invention. Programmable Time Delay unit 230 is programmed by Processor 140 to selectively impart a time delay to the clock signal applied to its input. When the TRIGGER pulse is locked with respect to a particular bit, the output clock signal from Programmable Delay unit 230 has a delay of zero. The divided output clock signal of Programmable Time Delay unit 230 is applied to an input of N-bit Bumpable Counter 250. N-bit Bumpable Counter 250 is a self-loaded down counter (also called a Holdoff counter). It begins counting down from a pre-loaded Count Value “N”, wherein “N” is equal to the pattern length “n”, and upon reaching a count of Zero, produces a COUNTDOWN EVENT output from its ZERO output port. The COUNTDOWN EVENT output from its ZERO output port is coupled to its LOAD input, causing N-bit Bumpable Counter 250 to reload the Count Value “N” at its LOAD VALUE input. The COUNTDOWN EVENT output from its ZERO output port is also coupled to the clock input of Trigger Generator circuit 240, and cooperates with the Scope Ready signal at the ENABLE input and the Acquisition Start (ACQINIT) signal to cause Trigger Generator circuit 240 to generate a TRIGGER output. When it is desired to shift the TRIGGER along the serial bit sequence, the Programmable Time Delay unit 230 in conjunction with the N-bit Bumpable counter 250 provides respective coarse and fine positioning of the TRIGGER along the serial bit sequence.

When it is desired to shift the TRIGGER along the serial bit sequence, Programmable Time Delay unit 230 in conjunction with the N-bit Bumpable counter 250 provides respective coarse and fine positioning of the TRIGGER along the serial bit sequence. An Alternate Load Value “V” is provided to the ALTERNATE LOAD VALUE port of N-Bit Bumpable Counter 250 from the processor 140, wherein the optimal value of “V” is equal to “N”±“(N÷S)”. If the difference between the current bit position of the locked TRIGGER and the new desired bit position to lock the TRIGGER is a multiple of “S”, then the Programmable Time Delay unit 230 has a Time Delay Value (TD) of zero. If the difference between the current bit position of the locked TRIGGER output and the new desired bit position to lock the TRIGGER output is not a multiple of “S”, then the Alternate Load Value “V” of the N-Bit Bumpable Counter 250 increments the new desired trigger lock bit position in units of 5 bits and the Time Delay Value to Programmable Time Delay unit 230 increments the new desired trigger lock bit position in units of 1 bit. The divided and delayed output clock signal of Programmable Time Delay unit 230 is applied to the input of N-bit Bumpable Counter 250. It begins counting down from the Alternate Load Value “V” after the time delay from the Programmable Time Delay unit 230, if present, and upon reaching a count of Zero, produces an output COUNTDOWN EVENT output from its ZERO output port. The COUNTDOWN EVENT output from its ZERO output port is coupled to its LOAD input, causing N-bit Bumpable Counter 250 to load the Count Value “N” at its LOAD VALUE input. The COUNTDOWN EVENT output from its ZERO output port is also coupled to the clock input of Trigger Generator circuit 240, and cooperates with the Scope Ready signal at the ENABLE input and the Acquisition Start (ACQINIT) signal to cause Trigger Generator circuit 240 to generate a TRIGGER output. One of ordinary skill in the art will recognize that the Alternate Load Value “V” need not be restricted to values of “N”±“(N÷S)” and that other Alternate Load Value may be used. However, the other Alternate Load Values can decrease the overall Trigger output frequency of the Position Lock Trigger circuitry 200. One skilled in the art will also recognize that the generated TRIGGER output is applied to the acquisition circuitry to cause triggered operation of the oscilloscope in the usual manner. While the following drawings show the TRIGGER output as a pulse, one skilled in the art will also recognize that the TRIGGER output may be a rising or falling edge that changes states with a reset pulse prior to the next TRIGGER output. The term “Bumpable” as used herein, means “able to be incremented or decremented by one or more bits at a time”.

A first example of shifting the TRIGGER from an initial bit position in the serial bit sequence to a new position in the serial bit sequence is described below. The length of the bit pattern “N” is “30” and the divide-by value “S” of the Divide by “S” circuit 225 is equal to “5”, resulting in the Count Value to the N-Bit Bumpable Counter 250 being 30. The effective result of dividing the clock by “5” is incrementing the bits in the serial bit sequence by the value of “S”, which in this example is “5”. The TRIGGER is initially locked at BIT 5 in the serial bit sequence and the new desired trigger lock bit position is “15”. Since the difference between the initial trigger lock bit position and the new desired trigger lock bit position has a value of “10”, which is a multiple of “5”, and the new desired trigger lock bit position shifts the TRIGGER to the right, then the Alternate Load Value “V” at the ALTERNATE LOAD VALUE port of N-Bit Bumpable Counter 250 is set at a value of “32” and the Time Delay Value to the Programmable Time Delay 230 is set to zero. The TRIGGER is then locked at BIT 15 in the serial bit sequence. Increasing the initial count of the N-bit Bumpable Counter 250 from 30 to 32 shifts the TRIGGER by a value of “10” (2·5). Since the new desired trigger lock bit position has a value that is a multiple of “5”, there is no need to add additional delay to the divided clock signal.

A second example of shifting the TRIGGER output from an initial bit position in the serial bit sequence to a new position in the serial bit sequence is described below. The length of pattern “N” and the divide-by value “S” are the same, resulting in an “N” Count Value equal to 30. The TRIGGER is initially locked again at BIT 5 in the serial bit sequence and the new desired trigger lock bit position is now “23”. Since the difference between the initial lock bit position and the new desired trigger lock bit position has a value of “18”, which is not a multiple of “5”, the Alternate Load Value “V” at the ALTERNATE LOAD VALUE port of N-Bit Bumpable Counter 250 is set at a value of 33 and the Time Delay Value to the Programmable Time Delay 230 is set to “3”. Increasing the initial count of the N-bit Bumpable Counter 250 from 30 to 33 shifts the new desired trigger lock bit position by a value of “15” (3·5), resulting in the positioning of the new desired trigger lock bit position at BIT 20 in the serial bit sequence. The Delay Value “3” delays the start of the divided clock to the N-bit Bumpable Counter 250 by three non-divided clocks, resulting in the positioning of the new desired trigger lock bit position at BIT 23.

Referring to FIG. 3a, a Serial Bit Sequence 300, corresponding to a sample stream, is representatively shown with every fifth BIT of the Serial Bit Sequence 300 being sampled by clock pulses 310. Between every fifth BIT are five BITS sampled by the clock pulses 310. This allows the logical state of each of the serial data bits to be determined. The Serial Bit Sequence 300 is illustrated in this manner to represent the clocking of the Programmable Time Delay unit 230 by the Divide by “S” circuit 225 having a divide-by “S” value of five, wherein five BITS of the Serial Bit Sequence 300 are clocked for every divided clock of the Divide by “S” circuit 225. Serial Bit Sequence 300 is shown as being broken into three portions corresponding to three acquisitions of five pattern length each. Because five BITS of the Serial Bit Sequence 300 are clocked for every divided clock of the Divide by “S” circuit 225, the Count Value “N” loaded at the LOAD VALUE input of the N-bit Bumpable counter 250 is effectively equal to (N·S), resulting in five pattern lengths occurring between each TRIGGER output. The use of a divide-by value of five is by example only, and other divide-by values are contemplated.

Referring to FIG. 3b, Counter 250 of FIG. 2 is programmed to inhibit the generation of a COUNTDOWN EVENT output for the number of edges equivalent to five full pattern lengths “n”. The Programmable Time Delay unit 230 is programmed to have a time delay value of zero. The combination of the Counter 250 and the Programmable Time Delay unit 230 causes the trigger system to generate a single TRIGGER output per five pattern length, giving the effect of the pattern being “locked” at the selected position, making it “stand still” (i.e., be stable) on the oscilloscope display.

In this regard, Counter 250 operates according to internal count sequences 330, 340, and 350. Internal count down sequence 330 counts down to a zero count 331, and loads a new Count Value “N” at location 331 of the sequence, wherein N is the entire pattern length “n”. The loading of Count Values in the N-bit Bumpable Counter 250 needs to occur within one cycle of the clock. TRIGGER 320 occurs at the zero count location 331, which corresponds to the BIT 10 position on Serial Bit Sequence 300. Thus, the next TRIGGER 322 occurs when the Count Value “N” has been decremented to zero at BIT 10+(N), keeping in mind that the Count Value “N” is equivalent to (N·S). Internal count sequence 340 counts down to a zero count 341, and reloads the “N” Count Value at location 341. The next TRIGGER 324 occurs when the Count Value “N” has been decremented to zero at BIT 10+2(N). Internal count down sequence 350 counts down to a zero count 351, and loads a new Count Value “N” at the same location 351. As noted, TRIGGER 320 occurred at the zero count location 331, which corresponded to the BIT 10 position on Serial Bit Sequence 300. TRIGGER 322 occurs at the zero count location 341, which corresponds to BIT 10+(N) position on Serial Bit Sequence 300. TRIGGER 324 occurs at the zero count location 351, which corresponds to BIT 10+2(N) position on Serial Bit Sequence 300 Therefore, subsequent TRIGGERS 324 will continue to occur the same point in each subsequent pattern, thus causing a stable display on the screen of display device 135 of FIG. 1.

Referring to FIG. 3c, when a user wants to navigate from one locked position to another, and thus view any portion of the Serial Bit Sequence 300 of the received serial stream, the user can “bump” (i.e., increment or decrement) the locked trigger position by one or more data bits at a time. In this embodiment, the locked trigger position is “bumped” by causing Programmable Time Delay unit 230 to impart a delay to the clock pulses applied to counter 250 and/or causing the count down of the N-Bit Bumpable Counter 250 to increase or decrease, or a combination of both. The time delay is imparted by interrupting the flow of the clock pulses through Programmable Time Delay unit 230 for a time controlled by Processor 140, and the count down increase or decrease of the N-bit Bumpable Counter 250 being controlled by the processor 140 in response to data input by a user. The user can operate any of the I/O circuitry 150 mentioned above (i.e., touch screen, keyboard, mouse, etc.) to enter information as to which bit should serve as the TRIGGER point. In response, Processor 140 applies an appropriate TIME DELAY VALUE to Programmable Time Delay unit 230 and Count Value to the N-bit Bumpable Counter 250, and controls the Programmable Time Delay unit 230 and the N-bit Bumpable Counter 250, to execute the delay period and the increased or decreased Count Value once.

As described above, the Programmable Time Delay unit 230 and the N-bit Bumpable Counter 250 operate according to internal count sequences 370, 380, and 390. Internal count sequence 370 counts down to a zero count 371, and loads an Alternate Load Value “V”, equal to (N+2), at the same location 371 of the count down sequence. At the same time, a Time Delay Value (TD) is provided to the Programmable Time Delay unit 230. TRIGGER 360 occurs at the zero count location 371, which corresponds to the BIT 10 position on Serial Bit Sequence 300. The next TRIGGER 362 occurs at BIT 22 position on Serial Bit Sequence 300 as a result of the Alternate Load Value “V” increasing in value from (N) to (N+2) and the Time Delay Value (TD) increasing from zero to 2. The first divided clock output from the Programmable Time Delay unit 230 is delayed 2 non-divided clocks before being applied to the N-bit Bumpable Counter 250. The Alternate Load Value “V” count is increased by two which delays the TRIGGER 362 by 10 BITS (2 Counts·5 BITS) in the Serial Bit Sequence 300. The combination of the delaying of the divided clock output of the Programmable Time Delay unit 230 by 2 non-divided clocks and increasing the Alternate Load Value “V” by 2 results in the Trigger point moving 12 BITS within the Serial Bit Sequence 300. Thus, the next TRIGGER 362 occurs when the Alternate Load Value “V” had been decremented to zero at (BIT 10+TD+V), corresponding to BIT 22. Internal count sequence 380 counts down to a zero count 381, corresponding to the BIT 22 on Serial Bit Sequence 300, and loads Count Value “N” at the same location 381 of the sequence. The next TRIGGER 364 occurs when the Count Value “N” has been decremented to zero at BIT 22+N. Internal Count down sequence 590 counts down to a zero count 591, and loads a new Count Value “N” at location 391. As noted, TRIGGER 360 occurred at the zero count location 371, which corresponds to the BIT 10 position on Serial Bit Sequence 300. TRIGGER 362 occurs at the zero count location 381, which corresponds to the BIT 22 position on Serial Bit Sequence 300. TRIGGER 364 occurs at the zero count location 391, which corresponds to the BIT 22+N position on Serial Bit Sequence 300. Therefore, subsequent TRIGGER pulses 364 will continue to occur at the same bit position (i.e., BIT 22) in each subsequent pattern, thus causing a stable display on the screen of display device 135 of FIG. 1.

The Position Lock Trigger circuitry may also include a pattern bit sequence recognizer 126 for identifying a pattern bit sequence 394 within the Serial Bit Sequence 300. The pattern bit sequence recognizer 126 operates on serial bit sequences having a repeating pattern. A user defines the pattern bit sequence 394, such as [10110] is preferably stored in memory 155. The processor 140 initiates a pattern bit sequence recognizer 126 algorithm that searches through the acquired Serial Bit Sequence 300 for the pattern bit sequence 394. When the pattern bit sequence 394 is found (e.g. BIT 22 in the Serial BIT Sequence 300), the processor 140 calculates an Alternate Count Value “V” and Time Delay Value based on the bit position of the start of the pattern bit sequence 394 in relation to the current bit position TRIGGER 360, which is BIT 10 in FIG. 3c. Internal count down sequence 370 counts down to a zero count 371, and loads the new Time Delay Value (TD) in the Programmable Time Delay 230 and the Alternate Count Value “V” in the N-Bit Bumpable Counter 250. TRIGGER 352 occurs at the zero count location 381, which corresponds to the BIT 22 position of the start of the pattern bit sequence 394 in Serial Bit Sequence 300. Location 381 of internal count sequence 380 once again loads a Count Value of “N”, wherein “N” is equals the pattern length “n”. The next TRIGGER 364 occurs when the Count Value “N” has been decremented to zero. Internal count down sequence 390 counts down to a zero count 391, and loads a new Count Value “N” at location 391. Therefore, subsequent TRIGGERS 364 will continue to occur at the same point (i.e., the start of the bit pattern sequence 394) in subsequent patterns, thus causing a stable display on the screen of display device 135 of FIG. 1. The pattern bit sequence recognizer may also be implemented in hardware circuitry, such as a Field Programmable Gate Array (FPGA), that is programmed with the user defines the pattern bit sequence 394. The acquired Serial Bit Sequence 300 is provided to the FGPA that searches through the Serial Bit Sequence 300 for the pattern bit sequence 394. Upon detecting the pattern bit sequence 394, the processor 140 calculates the Alternate Count Value “V” based on the bit position of the start of the pattern bit sequence 394 in relation to the current zero count location 371 for TRIGGER 360 in the internal count down sequence 370.

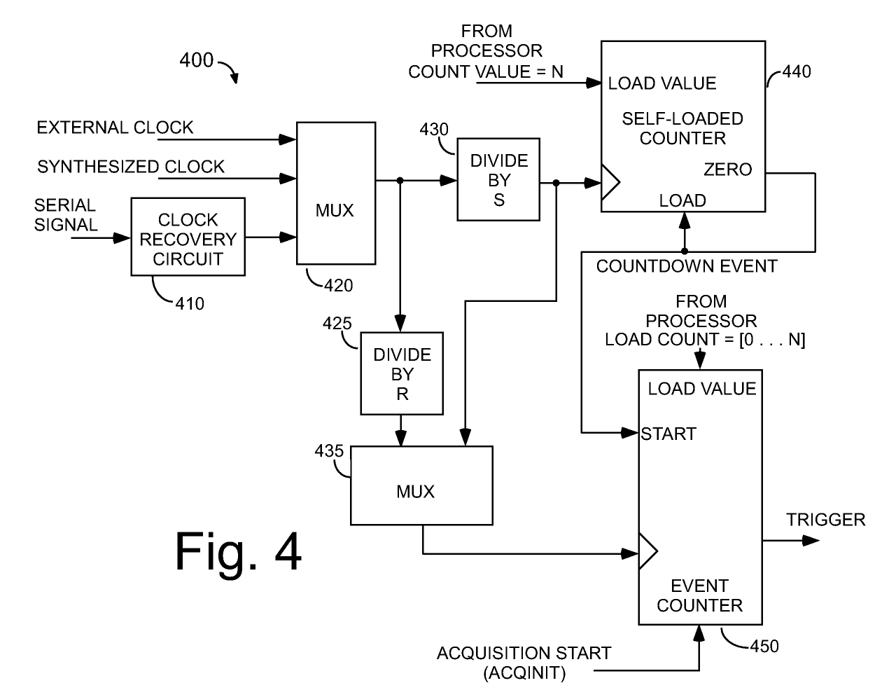

FIG. 4 is a more detailed view of a second embodiment of Serial Trigger block 123 of FIG. 1. Referring to FIG. 4, controlling the locked trigger position is accomplished by use of a variable r Load Count applied to an Event Counter 450. Varying the Load Count advances or delays the generation of a trigger as a function of a clock signal, with the result being the locked trigger position “shifts” left or right along the received serial bit sequences of the sample streams, bringing a different portion of the Serial Bit Sequence into view. In this way, a stable view of the received data at any position along the Serial Bit Sequence is obtained.

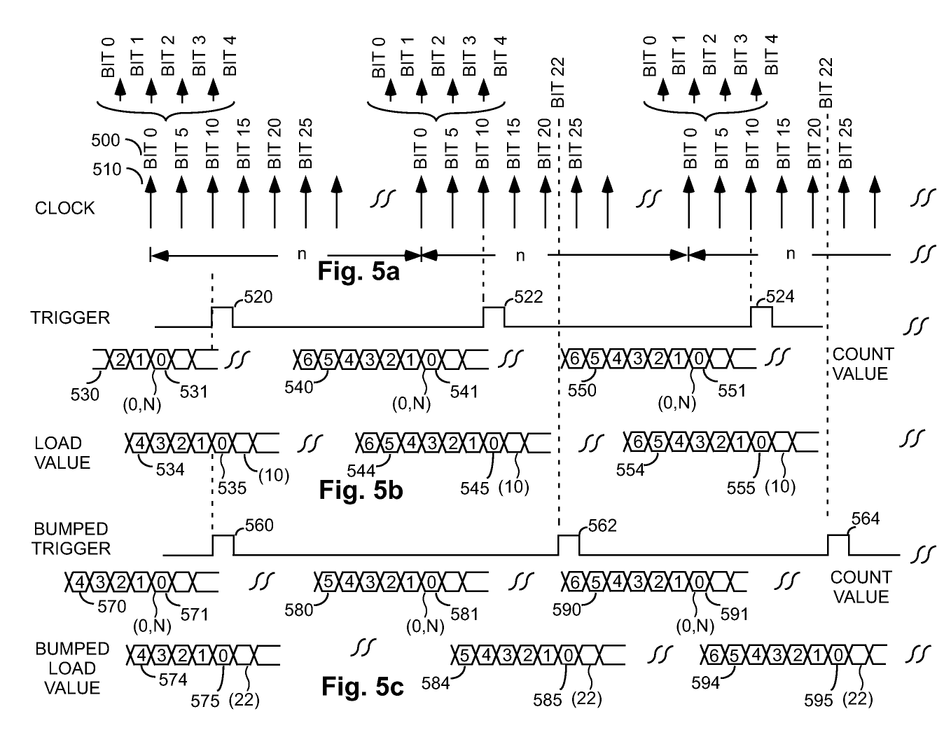

The second embodiment of the subject invention will now be described with respect to FIGS. 4, 5a, 5b, and 5c. Position Lock Trigger circuitry 400 includes at least a first input for receiving an external clock, a clock signal derived by use of a Clock Recovery Circuit 410, or a synthesized clock signal based on a requested bit rate or additional inputs for receiving two or more of the clock signals. In the event that two or more clock choices are provided, a Multiplexer (MUX) 420 is provided to select one of the multiple clock signals. The selected clock is applied to a Divide by S circuit 430 where “S” preferably has a value of 2, 5 or 10 to divide a clock signal having a frequency greater than the operating characteristics of a Self-Load Counter 440. The “divided down clock” from Divide by S circuit 430 is applied to an input of a Self-Loaded Counter 440 and may be optionally applied to a Multiplexer 435. The selected clock is may optionally be applied to a Divide by R circuit 425 where “R” preferably has values of 1, 2, 5 or 10. One or ordinary skill in the art will recognize that the Divide by R circuit 425 with “R” equal to one is equivalent to a pass through line equivalent to an electrically conductive trace or wire. In general, the values of “S” and “R” may be any set of related integers that are divisible by or a multiple of a common integer. The divided clock output of the Divide by R circuit 425 is applied to the Multiplexer 435. The Multiplexer 435 selects one of the two divided clocks which is applied to a clock input of an Event Counter 450. The Self-Loaded Counter 440 starts counting down from a pre-loaded Count Value programmed by the processor 140 to equal “N”, wherein “N” is equal to the pattern length “n”. Upon reaching a count of zero, the Self-Loaded Counter 440 produces a COUNTDOWN EVENT output. The COUNTDOWN EVENT output from its ZERO output port is coupled to its LOAD input, causing Self-Loaded Counter 440 to load the Count Value “N”, to its LOAD VALUE input. The COUNTDOWN EVENT output from its ZERO output port is also coupled to a START input of an Event Counter 450. The Event Counter 450 receives a Load Count programmed by the processor 140 at its LOAD VALUE input, wherein the Load Count value is preferably equal to (1 to (N (S)), wherein “N” is the pattern length “n” and “S” is the divide by value for the Divide by “S” circuit 430. The maximum Load count value is not restricted to (N (S)) and larger numbers may be used. The Event Counter 450 counts down the Load Count using the clock signal from the Multiplexer 420 or alternately from the Multiplexer 435 at the Event Counter clock input. When the Load Count decrements to zero, it cooperates with a Scope Ready signal at the ENABLE input and an Acquisition Start (ACQINIT) signal to cause Event Counter circuit 450 to generate a TRIGGER output. One skilled in the art will recognize that the generated TRIGGER output is applied to the acquisition circuitry to cause triggered operation of the oscilloscope in the usual manner.

Referring to FIG. 5a, a Serial Bit Sequence 500, corresponding to a sample bit steam, is representatively shown with every fifth BIT of the Serial Bit Sequence 500 being sampled by a clock pulse 510. Between every fifth BIT are five BITS sampled by the clock pulse 510. This allows the logical state of each of the serial data bits to be determined. The Serial Bit Sequence 500 is illustrated in this manner to represent the clocking of the Self-Loaded Counter 440 by the Divide by “S” circuit 630 having a divide-by “S” value of five, wherein five BITS of the Serial Bit Sequence 500 are sampled by clock pulses 510 for every divided clock Divide by “S” circuit 430. Serial Bit Sequence 500 is shown as being broken into three portions corresponding to three acquisitions of five pattern length each. Because five BITS of the Serial Bit Sequence 500 are clocked for every divided clock of the Divide by “S” circuit 425, the Count Value “N” loaded at the LOAD VALUE input of the Self-Loaded Counter 440 is effectively equal to (N·S) resulting in five pattern lengths occur between each TRIGGER output. The use of a divide-by value of five is by example only, and other divide-by values are contemplated.

Referring to FIG. 5b, Self-Loaded Counter 440 of FIG. 4 is programmed to inhibit the generation of a COUNTDOWN EVENT output for the number of edges equivalent to five full pattern lengths “n” and the Event Counter inhibits the generation of a TRIGGER output for the number of clock edges equivalent to the Load Count value. This causes the trigger system to generate a single TRIGGER output per five pattern length, giving the effect of the pattern being “locked” at the selected position, making it “stand still” (i.e., be stable) on the oscilloscope display.

In this regard, Self-Loaded Counter 440 and Event Counter 450 operate according to internal count sequences 530, 534, 540, 544, 550, 554 and 570, 574, 580, 584, 590, 594. In the below description, the initial TRIGGER is at the BIT 0 position in the Serial Bit Sequence 500 when the Load Count of the Event Counter 450 is “0”. However, the initial TRIGGER may at any position in the serial bit stream. Internal count down sequence 530 of the Self-Loaded Counter 440 counts down to a zero count 531, generates a COUNTDOWN EVENT output and loads a new Count Value “N” at location 531 of the sequence, wherein “N” is the pattern length “n”. The loading of Count Values in the Self-Loaded Counter 440 needs to occur within one cycle of the clock. The COUNTDOWN EVENT output initiates an internal count down sequence 534 in the Event Counter 450 from Load Count value (10) to a zero count 535 to produce a TRIGGER 520, which corresponds to the BIT 10 position on the Serial Bit Sequence 500. The same Load Count value (10) is reloaded into the Event Counter 450 prior to the zero count of the Self-Loaded Counter 440. It should be noted that Load Count of the Event Counter 450 may have a minimum value of 1 resulting in at least one clock event to produce TRIGGER 520 resulting in the TRIGGER 520 occurring at one clock after the COUNTDOWN EVENT output. TRIGGER 522 occurs when the internal count down sequence 540 of the Self-Loaded Counter 440 counts down to a zero count 541 and loads a new Count Value “N” at location 541 of the sequence, and the COUNTDOWN EVENT output initiates an internal count down sequence 544 of the Event Counter 450 from Load Count value (10) to a zero count 545, which corresponds to BIT 10+(N) position on the Serial Bit Sequence 500. Again, the same Load Count value (10) is reloaded into the Event Counter 450 prior to the zero count of the Self-Loaded Counter 440. The internal count down sequence 550 of the Self-Loaded Counter 440 again counts down to zero count 551 and loads a new Count Value “N” at location 541 of the sequence. The COUNTDOWN EVENT output initiates an Internal count down sequence 554 of the Event Counter 450 from Load Count value (10) to a zero count 555 to produce a TRIGGER 524, which corresponds to the BIT 10+2(n) position on the Serial Bit Sequence 500. The same Load Count value (10) is again reloaded into the Event Counter 450 prior to the zero count of the Self-Loaded Counter 440. As noted, TRIGGER 520 occurred at the zero count location 535, which corresponded to the BIT 10 position on Serial Bit Sequence 500. TRIGGER 522 occurs at the zero count location 545, which corresponds to BIT 10+(n) position on Serial Bit Sequence 500. TRIGGER 524 occurs at the zero count location 555, which corresponds to BIT 10+2(n) position on Serial Bit Sequence 500. The combination of the constant repetitive internal count down sequence of the Self-Loaded Counter 440 and a constant repeating Load Count value cause subsequent TRIGGERS 524 to occur the same point in subsequent patterns, thus causing a stable display on the screen of display device 135 of FIG. 1.

Referring to FIG. 5c, when a user wants to navigate from one locked trigger position to another, and thus view any portion of the received serial stream data, the user can “bump” (i.e., increment or decrement) the locked trigger position by one or more data bits at a time. In this embodiment, the locked trigger position is “bumped” by increasing or decreasing the Load Count value provided to the Event Counter 450. The user can operate any of the I/O circuitry 150 mentioned above (i.e., touch screen, keyboard, mouse, etc.) to enter information as to which bit should serve as the TRIGGER point. In response, Processor 140 applies an appropriate Load Count value to the Event Counter 450, and the Event Counter 450 counts down the Load Count value to zero for each subsequent zero count of the Self-Loaded Counter 440.

As described above, the Event Counter 450 operates by receiving a Load Count value from the processor 140 and in response to a COUNTDOWN EVENT output provided by the Self-Loaded Counter 440 counts down from the Load Count value to zero and produces a TRIGGER out. FIG. 5c relates to internal count sequences 570, 574, 580, 584, 590 and 594. Internal count down sequence 570 of the Self-Loaded Counter 440 counts down to a zero count 571 and loads a new Count Value “N” at location 571 of the sequence, wherein “N” is the pattern length “n”. The COUNTDOWN EVENT output initiates internal count down sequence 574 of the Event Counter 450 from a Load Count value (10) to a zero count 575 to produce a TRIGGER 560, which corresponds to the BIT 10 position on the Serial Bit Sequence 500. A new Load Count value (22) is reloaded into the Event Counter 450 prior to the zero count of the Self-Loaded Counter 440. TRIGGER 562 occurs when the internal count down sequence 580 of the Self-Loaded Counter 440 counts down to a zero count 581 and loads a new Count Value “N” at location 581 of the sequence. The COUNTDOWN EVENT output initiates internal count down sequence 584 of the Event Counter 450 from the Load Count value (22) to a zero count 585, which corresponds to the BIT 22 position on the Serial Bit Sequence 500. The same Load Count value (22) is reloaded into the Event Counter 450 prior to the zero count of the Self-Loaded Counter 440. The internal count down sequence 590 of the Self-Loaded Counter 440 again counts down to zero count 591 and loads a new Count Value “N” at location 591 of the sequence. The COUNTDOWN EVENT output initiates internal count down sequence 594 of the Event Counter 650 counts down from the Load Count value (22) to a zero count 595 to produce a TRIGGER 524, which corresponds to the BIT 22+(n) position on the Serial Bit Sequence 500. As noted, TRIGGER 550 occurred at the zero count location 575, which corresponded to BIT 10 position on Serial Bit Sequence 500. TRIGGER 552 occurs at the zero count location 585, which corresponds to the BIT 22 position on Serial Bit Sequence 500. TRIGGER 564 occurs at the zero count location 595, which corresponds to the BIT 22+(n) position on Serial Bit Sequence 500. Increasing or decreasing the Load Count value of the Event Counter 450 shifts the TRIGGER in the Serial Bit Sequence 500 thus changing the trigger lock point in the Serial Bit Sequence 500 and results in subsequent TRIGGERS 564 to occur the same shifted TRIGGER position in subsequent patterns, thus causing a stable display on the screen of display device 135 of FIG. 1. As described with the previous embodiment, the Position Lock Trigger circuitry 400 may also include a pattern bit sequence recognizer for identifying a pattern bit sequences and shifting the TRIGGER to the start of a pattern bit sequence.

To extend the bit rates obtainable when a recovered clock is used, the recovered clock can be programmed to lock onto a fraction of the user input frequency, adjusting the trigger position skew to compensate. In this case the number of edges delayed is reduced by the fractional amount, and an additional acquisition skew equivalent to one bit is applied to the shift operation for every other bit. This maintains the capability of navigating along the serial data one or more bits at a time.

Typical fraction amounts are two for NRZ serial data, or ten for 8b10b serial data. In the recovered clock case, the input data signal must contain a sufficient number of edges to keep the recovered clock circuits locked to the fractional signal frequency. Use of fractional bit rates and compensating trigger position skews not only makes the trigger circuits effective over a broader bit rate range, and thus less expensive to construct, but also allows circumvention of the bandwidth holes that occur as a result of the finite time required to re-load the holdoff counters.

By use of the subject invention, examination of the signal can be done to even higher bit rates with less expensive circuitry than is used in traditional serial pattern matching circuits. This is accomplished taking advantage of a unique “holdoff-by-events” circuit along with counters, clock dividers, event-sequencing, and related circuits already included in an oscilloscope advanced trigger ASIC designed for use in certain Tektronix oscilloscopes. In this regard, see U.S. Pat. No. 7,191,079, Oscilloscope Having Advanced Triggering Capability, issued 13 Mar. 2007, and U.S. Pat. No. 4,980,605, Oscilloscope Triggering Control Circuit, issued 25 Dec. 1990, both herein incorporated by reference.

It should be noted that end-to-end signal examination can be accomplished without having to match a bit pattern in the serial stream. However, should the serial stream be known to contain a particular bit sequence, that information can be used to lock the trigger position where the pattern occurs. The circuit can lock the position on serial NRZ, 8b10b, or other coded serial signals.

While N-bit Bumpable Counter 450, and the Event Counter 650 have been described as down-counters, it will be recognized that they may also be realized as up-counters with suitable modification of the loaded counts, or a combination of both. One should also note that the function of Clock Recovery circuit 410, 610 could be performed in software. These modifications are intended to be covered by the following claims

1. A position lock trigger circuit for use in an oscilloscope, comprising:
a control circuit controlling said oscilloscope to trigger in the same bit position in a Serial bit sequence using coarse and a fine trigger adjustments;
in response to user input, said control circuit causes said oscilloscope to trigger in a different bit position on a following Serial bit sequence using said coarse and a fine trigger adjustments;
thereafter said control circuit controlling said oscilloscope to trigger in the same bit position as said different bit position in subsequent serial bit sequences using said coarse and a fine trigger adjustments.

2. The Position Lock Trigger circuit of claim 1 wherein:
said control circuit comprises a pattern bit sequence recognizer responsive to a user input;
a controller providing said Serial bit sequence to said pattern bit sequence recognizer for locating a pattern bit sequence in said serial bit sequence; and
in response to located a pattern bit sequence, said control circuit causes said oscilloscope to trigger in a different bit position defined by said pattern bit sequence in subsequent Serial bit sequence using said coarse and a fine trigger adjustments.

3. The Position Lock Trigger circuit of claim 1 wherein:
said control circuit comprises a counter responsive to a clock signal; and
in response to user input, said control circuit causes said oscilloscope to trigger in a different bit position in a following Serial bit sequence by changing a beginning count using coarse trigger adjustments and delaying said clock signal to said counter for a predetermined period of time using said fine trigger adjustments.

4. The Position Lock Trigger circuit of claim 3 wherein:
said control circuit comprises a multiplexer for selecting among a clock recovered from said serial bit sequence, an external clock and a synthesized clock.

5. The Position Lock Trigger circuit of claim 4 wherein:
said control circuit comprises a clock recovery circuit for deriving said clock recovered from said serial bit sequence

6. The Position Lock Trigger circuit of claim 1 wherein:
said control circuit comprises a counter responsive to a clock signal; and
in response to user input, said control circuit causes said oscilloscope to trigger in a different bit position on a following acquisition of said Serial bit sequence by changing the beginning count to change a counting period as said fine trigger adjustment.

7. The Position Lock Trigger circuit of claim 6 wherein:
said control circuit comprises a multiplexer for selecting among a clock recovered from said serial bit sequence, an external clock and a synthesized clock.

8. The Position Lock Trigger circuit of claim 7 wherein:
said control circuit comprises a clock recovery circuit for deriving said clock recovered from said serial bit sequence

9. A Position Lock Trigger circuit for use in an oscilloscope, comprising:
a divide by S circuit having an input receiving a clock signal and producing a divided clock signal at a rate determined by the value of S;
a programmable clock delay circuit receiving said divided clock signal and an N-bit Time Delay Value and producing a delayed, divided clock signal; and
a counter circuit receiving said delayed, divided clock signal and an N-bit Count Value and counting from said N-bit Count Value to a terminal value in accordance with said received delayed divided clock signal, said counter producing a signal indicative of reaching said terminal count; and
a trigger generator circuit responsive to said signal indicative of reaching said terminal count to produce a trigger; wherein
said programmable clock delay circuit and said counter circuit operating in a first mode such that said N-bit Time Delay Value provides fine trigger adjustment and said N-bit Count Value provides coarse trigger adjustment and triggers said oscilloscope in the same bit position on acquisitions of said serial bit sequence; and
in response to user input, said programmable clock delay circuit and said counter circuit operate in a second mode such that said divided clock pulses are delayed from being developed at said programmable clock delay circuit output for a period of time related to said N-bit Time Delay Value to provide a fine trigger adjustment and said counter circuit receiving said delayed, divided clock signal and an N-bit Alternate Load Value, and counting from said N-bit Alternate Load Value to a terminal value once in accordance with said received delayed, divided clock signal to provide a coarse trigger adjustment, said counter producing a signal indicative of reaching said terminal count said counter circuit;
said N-bit Time Delay Value and said N-bit Alternate Load Value exhibiting values such that said oscilloscope triggers in a different bit position in subsequent serial bit sequences.

10. The Position Lock Trigger circuit of claim 9 further comprising:
a pattern bit sequence recognizer responsive to a user input;
a controller providing said Serial bit sequence to said pattern bit sequence recognizer for locating a pattern bit sequence in said serial bit sequence; and
in response to located a pattern bit sequence, said N-bit Time Delay Value and said N-bit Alternate Load Value exhibiting values such that said oscilloscope triggers in a different bit position defined by said pattern bit sequence in subsequent serial bit sequences.

11. The Position Lock Trigger circuit of claim 9 further comprising:
a multiplexer selecting among a clock recovered from said serial bit sequence, an external clock and a synthesized clock.

12. The Position Lock Trigger circuit of claim 11 further comprising:
a clock recovery circuit deriving said clock recovered from said serial bit sequence.

13. A Position Lock Trigger circuit for use in an oscilloscope, comprising:
a divide by S circuit having an input receiving a clock signal and producing a divided clock signal at a rate determined by the value of S;
a counter circuit receiving the divided clock signal and an N-bit Count Value, and counting from said N-bit Count Value to a terminal value in accordance with said received divided clock signal, said counter producing a Countdown Event output indicative of reaching said terminal count; and
a counter circuit receiving said delayed, divided clock signal and an N-bit Count Value and counting from said N-bit Count Value to a terminal value in accordance with said received delayed divided clock signal, said counter producing a signal indicative of reaching said terminal count; and
an Event Counter circuit receiving said signal indicative of reaching said terminal count, said clock signal and a Count Value and counting from said Count Value to a terminal value in accordance with said received clock signal, said Event Counter producing a trigger output indicative of reaching said terminal count; wherein
said Count Value exhibiting a value such that said oscilloscope triggers in the same bit position in serial bit sequences;
in response to user input, said Event Counter circuit receiving a new Count Value and counting from said new Count Value to a terminal value in accordance with said received clock signal on receiving said signal indicative of reaching said terminal count, said Event Counter producing a signal indicative of reaching said terminal count;
said new Count Value exhibiting a value such that said oscilloscope triggers in a different bit position in subsequent serial bit sequences.

14. The Position Lock Trigger circuit of claim 14 further comprising:
a pattern bit sequence recognizer responsive to a user input;
a controller providing said Serial bit sequence to said pattern bit sequence recognizer for locating a pattern bit sequence in said serial bit sequence; and
in response to located a pattern bit sequence, said new Count Value exhibiting a value such that said oscilloscope triggers in a different bit position defined by said pattern bit sequence in subsequent serial bit sequences.

15. The Position Lock Trigger circuit of claim 14 further comprising:
a divide by R circuit having an input receiving said clock signal and producing a divided clock signal at a rate determined by the value of R;
a multiplexer selecting between said divided clock signal at a rate determined by the value of R and said divided clock signal at a rate determined by the value of S with selected divided clock signal coupled to said counter circuit.

16. The Position Lock Trigger circuit of claim 14 further comprising:
a multiplexer selecting among a clock recovered from said serial bit sequence, an external clock and a synthesized clock.

17. The Position Lock Trigger circuit of claim 16 further comprising:
a clock recovery circuit deriving said clock recovered from said serial bit sequence.
